(19) United States
(12) Patent Application Publication
(10) Pub. No.: US 2026/0058660 A1
(43) Pub. Date: Feb. 26, 2026

(54) Level-Shifter with Low Duty-Cycle Distortion Across Process, Voltage, and Temperature Corners

(71) Applicant: QUALCOMM Incorporated, San Diego, CA (US)

(72) Inventors: David PALOMEQUE, Cork (IE); Stefano FACCHIN, Munchen (DE)

(21) Appl. No.: 18/814,336

(22) Filed: Aug. 23, 2024

(51) Int. Cl. H03K 19/0185; H03K 3/356; H03K 5/156

(52) U.S. Cl. CPC H03K 19/018521; H03K 3/356113; H03K 3/356182; H03K 5/1565

(57) ABSTRACT

A level-shifter is provided that balances the pull-up and pull-down of a pair of internal nodes. To balance the pull-down of the internal nodes, a pull-down strength of a pull-down network is also responsive to a power supply voltage for the level-shifter. To balance the pull-up of the internal nodes, a pull-up strength of a pull-up network is also responsive to an amplitude of an input signal being level-shifted by the level-shifter.

### TECHNICAL FIELD

This application relates to level-shifters, and more particularly to a level-shifter with low duty-cycle distortion across process, voltage, and temperature (PVT) corners.

### BACKGROUND

As semiconductor technology has advanced into the deep submicron regime, the power supply voltage is scaled down in concert with the scaling down of transistor dimensions. For example, microprocessors are now manufactured with transistors powered by a sub-one-volt power supply voltage. But these modern systems may need to interface with peripheral devices such as memories that operate on higher supply voltages. The signal flow from the low-voltage domain to the high-voltage domain requires a shift up in voltage. Conversely, the signal flow from the high-voltage domain to the low-voltage domain requires a shift down in voltage. Level-shifters have thus been developed to shift signals from one power domain to another.

In a traditional level-shifter, a positive input signal that is to be level-shifted drives a gate of a first n-type metal-oxide semiconductor (NMOS) transistor that functions to discharge a negative output node when the positive input signal is asserted to a first power supply voltage for a first power domain. Prior to the discharge of the negative output node, a first p-type metal-oxide semiconductor (PMOS) transistor charged the negative output node to a second power supply voltage for a second power domain. The negative output node thus cycles between being discharged while the positive input signal is charged to the first power supply voltage to being charged to the second power supply voltage while the positive input signal is discharged to ground. Similarly, a negative input signal that is the complement of the positive input signal drives a gate of a second NMOS transistor that functions to discharge a positive output node when the negative input signal is asserted to the first power supply voltage. Prior to the discharge of the positive output node, a second PMOS transistor charged the positive output node to the second power supply voltage. The positive output node thus cycles between being discharged while the negative input signal is charged to the first power supply voltage to being charged to the second power supply voltage while the negative input signal is discharged to ground.

Suppose that the first power supply voltage is less than the second power supply voltage. The pull-down of the negative and positive output nodes by the first and second NMOS transistors will thus be weaker than the pull-up of the output nodes by the first and second PMOS transistors. The resulting imbalance between the pull-up and pull-down of the output nodes introduces a duty cycle distortion into the level-shifting of the input signals.

### SUMMARY

A level-shifter is disclosed that includes: a pull-down circuit configured to ground a first internal node in response to a first input signal being charged to a first voltage; a pull-up circuit configured to charge the first internal node to a power supply voltage in response to the first input signal being discharged from the first voltage to ground; a first inverter configured to invert a voltage of the first internal node to form a first output signal at an output terminal of the first inverter; a first transistor having a gate coupled to the output terminal of the first inverter; a second transistor coupled between the first transistor and ground and having a gate coupled to a node for the first input signal; and a first current mirror configured to mirror a current conducted by the first transistor into a mirrored current conducted into the first internal node.

In addition, a method of level-shifting is provided that includes the acts of: charging a first internal node through a first pull-up transistor in response to a first input signal transitioning from a first voltage to ground while a second input signal transitions from ground to the first voltage; conducting a first current while the second input signal transitions from ground to the first voltage; mirroring the first current into a mirrored first current that conducts into the first internal node to assist charging the first internal node to a power supply voltage; inverting a voltage of the first internal node to form a first output signal that discharges to ground in response to the second input signal transitioning from ground to the first voltage; and stopping the conducting of the first current to stop the mirroring of the first current into the mirrored first current in response to the first output signal discharging to ground.

Finally, a memory is provided that includes: a first internal node; a first pull-down transistor coupled between the first internal node and ground and having a gate coupled to a node for a first input signal; a second internal node; a second pull-down transistor coupled between the second internal node and ground and having a gate coupled to a node for a second input signal; a first pull-up transistor coupled between the first internal node and a node for a power supply voltage and having a gate coupled to the second internal node; a second pull-up transistor coupled between the second internal node and the node for the power supply voltage and having a gate coupled to the first internal node; a first capacitor coupled between the gate of the first pull-down transistor and the second internal node; and a second capacitor coupled between the gate of the second pull-down transistor and the first internal node.

These advantage features may be better appreciated by a consideration of the following detailed description.

### BRIEF DESCRIPTION OF THE DRAWINGS

FIG. 1 illustrates a first level-shifter in accordance with an aspect of the disclosure.

FIG. 2 illustrates a second level-shifter in accordance with an aspect of the disclosure.

FIG. 3 illustrates a third level-shifter in accordance with an aspect of the disclosure.

FIG. 4 illustrates a ring oscillator having its output signals level-shifted by level-shifters in accordance with an aspect of the disclosure.

FIG. 5 is a flowchart of an example method of level-shifting in accordance with an aspect of the disclosure.

Implementations of the present disclosure and their advantages are best understood by referring to the detailed description that follows. It should be appreciated that like reference numerals are used to identify like elements illustrated in one or more of the figures.

### DETAILED DESCRIPTION

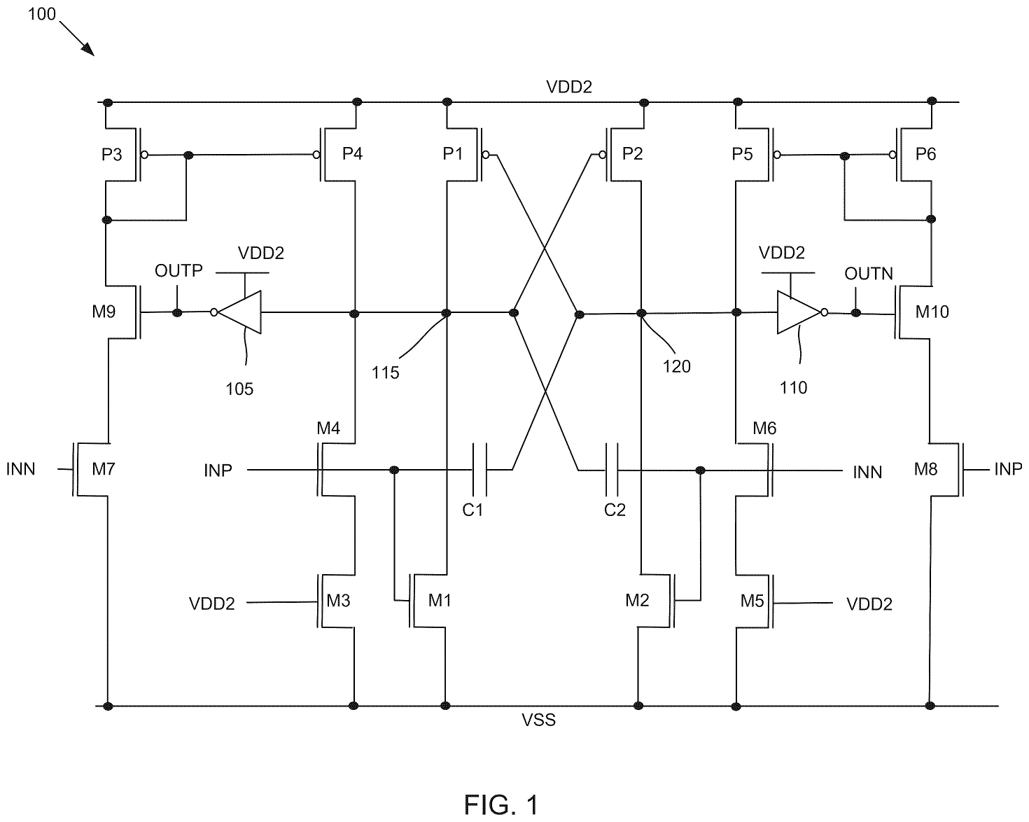

A level-shifter is disclosed with low duty-cycle distortion across process, voltage, and temperature corners. An example level-shifter 100 is shown in FIG. 1. A first NMOS pull-down transistor M1 has a source coupled to ground (VSS) and a drain coupled to a first internal node 115. A positive input signal (INP) from a first power domain drives a gate of the first pull-down transistor M1. When the positive input signal charges to a first voltage, the first pull-down transistor M1 switches on to discharge the first internal node 115 to ground. The following discussion will assume that the first voltage is a first power supply voltage (VDD1). For example, the first power supply voltage may be the peak amplitude of an oscillation output signal from a ring oscillator as will be further described herein. Similarly, a second NMOS pull-down transistor M2 has a source coupled to ground and a drain coupled to a second internal node 120. A negative input signal (INN) drives a gate of the second pull-down transistor M2. The negative input signal is a complement of the positive input signal. Thus, when the positive input signal discharges to ground, the negative input signal charges to the first voltage to switch on the second pull-down transistor M2 to discharge the second internal node 120 to ground.

The second internal node 120 couples to a gate of a first PMOS pull-up transistor P1 having a source coupled to a power supply node for a second power supply voltage (VDD2) that powers the level-shifter 100. A drain of the first pull-up transistor P1 couples to the first internal node 115. Thus, when the negative input signal is charged to the first voltage to cause the second pull-down transistor M2 to discharge the second internal node 120, the first pull-up transistor P1 switches on to charge the first internal node 115 to the second power supply voltage VDD2. The first internal node 115 will subsequently be discharged to ground in response to the positive input signal being charged to the first voltage to switch on the first pull-down transistor M1. But during this discharge of the first internal node 115, there is an initial struggle between the pull-down transistor M1 and the pull-up transistor P1. Should transistors M1 and P1 have approximately the same size, the relative strength of the transistors M1 and P1 in this struggle depends upon the magnitude of the first voltage as compared to the magnitude of the second power supply voltage VDD2. Should the second power supply voltage VDD2 be greater than the first voltage, the pull-up (charging towards VDD2) from the first pull-up transistor P1 will initially be stronger than the pull-down (discharging towards ground) from the first pull-down transistor M1. Conversely, the pull-down from the first pull-down transistor M1 will be stronger than the pull-up from first pull-up transistor P1 if the first voltage is greater than the second power supply voltage VDD2.

A similar struggle occurs with respect to the second internal node 120 in that a second PMOS pull-up transistor P2 has a source coupled to the power supply node for the second power supply voltage VDD2, a drain coupled to the second internal node 120, and a gate coupled to the first internal node 115. Thus, when the positive input signal is charged to the first voltage to cause the first pull-down transistor M1 to discharge the first internal node 115, the second pull-up transistor P2 switches on to charge the second internal node 120 to the second power supply voltage VDD2. The second internal node 120 will subsequently be discharged in response to the negative input signal being charged to the first voltage to switch on the second pull-down transistor M2. But during this discharge of the second internal node 120, there is an initial struggle between the second pull-down transistor M2 and the second pull-up transistor P2 that depends upon the magnitude of the first voltage as compared to the magnitude of the second power supply voltage VDD2.

With respect to the positive input signal, the pull-up transistor P1 and the pull-down transistor M1 form a first inverter having the internal node 115 as the output terminal of the first inverter. Similarly, the pull-up transistor P2 and the pull-down transistor M2 form a second inverter having the internal node 120 as the output terminal of the second inverter. These inverters are cross coupled to form a latch. For example, the internal node 115 couples to the gate of the second pull-up transistor P2 and also couples through a coupling capacitor C2 to the gate of the second pull-down transistor M2. Similarly, the internal node 120 couples to the gate of the first pull-up transistor P1 and also couples through a coupling capacitor C1 to the gate of the first pull-down transistor M1. The resulting latch may be designed to have an acceptable duty cycle for certain values of the positive/negative input signals and the second power supply voltage VDD2. But as these values change, the duty cycle suffers.

For example, a mismatch between the pull-down strength of the pull-down transistors M1 and M2 as compared to the pull-up strength of the pull-up transistors P1 and P2 may cause a duty-cycle distortion in the level-shifting of the input signals should the voltage of the first internal node 115 be used to form a negative output signal and the voltage of the second internal node 120 be used to form a positive output signal. To combat this duty-cycle distortion, the first internal node 115 also couples to ground through an NMOS third pull-down transistor M3 in series with an NMOS fourth pull-down transistor M4. The drain of the fourth pull-down transistor M4 couples to the first internal node 115 whereas its source couples to the drain of the third pull-down transistor M3. A source of the third pull-down transistor M3 couples to ground. The positive input signal drives the gate of the fourth pull-down transistor M4 whereas the second power supply voltage VDD2 drives the gate of the third pull-down transistor M3. The third pull-down transistor M3 is thus always switched on and functions to provide an on-resistance that is either reduced or increased depending upon the magnitude of the second power supply voltage VDD2. When the positive input signal swings high to the first voltage, the fourth pull-down transistor M4 assists in the discharge of the first internal node 115 with a pull-down strength that not only depends upon the magnitude of the first voltage but also on the magnitude of the second power supply voltage VDD2. As the magnitude of the second power supply voltage VDD2 increases, the pull-down strength from the pull-down transistors M3 and M4 on the first internal node 115 increases. Conversely, as the magnitude of the second power supply voltage VDD2 decreases, the pull-down strength from the pull-down transistors M3 and M4 on the first internal node 115 decreases. Should the second power supply voltage VDD2 be greater than the first voltage, the pull-down transistors M3 and M4 thus function to help equalize the pull-down versus the pull-up of the first internal node 115 because of the increased pull-down strength from the resulting relatively low on-resistance of pull-down transistor M3. The positive input signal is also denoted herein as a first input signal. Similarly, the negative input signal is also denoted herein as a second input signal.

An analogous pair of NMOS pull-down transistors M5 and M6 assist with respect to equalizing the pull-up and pull-down of the second internal node 120. The drain of the sixth pull-down transistor M6 couples to the second internal node 120 whereas its source couples to the drain of the fifth pull-down transistor M5. The negative input signal drives the gate of the pull-down transistor M6 whereas the second power supply voltage VDD2 drives the gate of the pull-down transistor M5. The source of the pull-down transistor M5 couples to ground. The pull-down transistor M5 is thus always switched on and functions to provide an on-resistance that is either reduced or increased depending upon the magnitude of the second power supply voltage VDD2. When the negative input signal swings high to the first voltage, the pull-down transistor M6 assists in the discharge of the second internal node 120 with a pull-down strength that not only depends upon the magnitude of the first voltage but also on the magnitude of the second power supply voltage VDD2. As the magnitude of the second power supply voltage VDD2 increases, the pull-down strength from the pull-down transistors M5 and M6 on the second internal node 120 increases. Conversely, as the magnitude of the second power supply voltage VDD2 decreases, the pull-down strength from the pull-down transistors M5 and M6 on the second internal node 115 decreases. Should the second power supply voltage VDD2 be greater than the first voltage, the pull-down transistors M5 and M6 thus function to help equalize the pull-down versus the pull-up of the second internal node 120 because of the increased pull-down strength from the resulting relatively low on-resistance of the pull-down transistor M5.

Should the first voltage be greater than the second power supply voltage VDD2, the pull-up of the first internal node 115 and of the second internal node 120 may be too weak as compared to the pull-down of these nodes. To assist the pull-up of the first internal node 115, the negative input signal drives a gate of an NMOS transistor M7 having a source coupled to ground and a drain coupled to a source of an NMOS transistor M9. The drain of the transistor M9 couples to a gate and drain of a diode-connected PMOS transistor P3 having a source coupled to the power supply node for the second power supply voltage VDD2. The gate and drain of the diode-connected transistor P3 also couple to a gate of a PMOS transistor P4 having a source coupled to the power supply node for the second power supply voltage VDD2 and a drain coupled to the first internal node 115. Transistors P3 and P4 thus form a current mirror. Transistor M7 will switch on in response to the negative input signal charging to the first voltage and conduct a first current into ground (assuming that transistor M9 is initially on). This current is mirrored through transistors P3 and P4 to form a first mirrored current that conducts into the first internal node 115 to assist in the charging of the first internal node 115 to the second power supply voltage VDD2. Should the second power supply voltage VDD2 be less than the first voltage, transistors M7, P3, and P4 thus function to increase the pull-up strength of the first internal node 115 as compared to its pull-down strength.

Although transistors M7, P3 and P4 advantageously function to equalize the pull-up and pull-down of the first internal node 115, note that transistors P3 and M7 will continuously conduct a current into ground while the negative input signal is charged to the first voltage should the drains of transistors M7 and P3 be permanently coupled together. Transistor M9 advantageously functions to stop this continuous conduction to ground. In that regard, a first inverter 105 powered by the second power supply voltage VDD2 inverts the voltage of the first internal node 115 to produce a positive output signal (OUTP) at an output terminal of the first inverter 105. The positive output signal is also denoted herein as a first output signal. The first inverter 105 functions to charge the positive output signal to the second power supply voltage VDD2 in response to the first internal node 115 being grounded. The output terminal of the first inverter 105 also couples to the gate of transistor M9. The positive output signal was already charged high to the first voltage prior to the negative input signal rising high to the first voltage (the rising edge of the negative input signal). Thus, the transistor M9 is initially on when the negative input signal rises high, which allows transistors M7 and P3 to conduct a first current that is mirrored into transistor P4 to produce a mirrored first current conducted into the first internal node 115, which causes the first internal node 115 to charge high toward the second power supply voltage VDD2. This charging of the first internal node 115 causes the first inverter 105 to discharge the positive output signal, which switches off transistor M9 to prevent transistor M7 from conducting additional current into ground. In this fashion, power consumption is reduced. Transistor M9 is also denoted herein as a first transistor. Similarly, transistor M7 is also denoted herein as a second transistor.

The pull-up of the second internal node 120 is assisted analogously. To assist the pull-up of the second internal node 120, the positive input signal drives a gate of an NMOS transistor M8 having a source coupled to ground and a drain coupled to a source of an NMOS transistor M10. The drain of the transistor M10 couples to a gate and drain of a diode-connected PMOS transistor P6 having a source coupled to the power supply node for the second power supply voltage VDD2. The gate and drain of the transistor P6 also couple to a gate of a PMOS transistor P5 having a source coupled to the power supply node for the second power supply voltage VDD2 and a drain coupled to the second internal node 120. Transistors P5 and P6 thus form a current mirror. Assuming that transistor M10 is on, transistor M8 will switch on in response to the positive input signal charging to the first voltage and conduct a second current into ground. This second current is mirrored through transistors P6 and P5 to form a second mirrored current to assist in the charging of the second internal node 120 to the second power supply voltage VDD2. Should the second power supply voltage VDD2 be less than the first voltage, transistors M8, P6, and P5 thus function to increase the pull-up strength of the second internal node 120 as compared to the pull-down strength of this node. Transistor M10 is also denoted herein as a third transistor whereas transistor M8 is also denoted herein as a fourth transistor.

Although transistors M8, P6 and P5 advantageously function to equalize the pull-up and pull-down of the second internal node 120, note that transistor M8 will continuously conduct a current into ground while the negative input signal is charged to the first voltage should the drains of transistors M8 and P6 be permanently coupled together. Transistor M10 advantageously functions to stop this continuous conduction to ground. In that regard, a second inverter 110 powered by the second power supply voltage VDD2 inverts the voltage of the second internal node 120 to produce a negative output signal (OUTN) at an output terminal of the second inverter 110. The negative output signal is also denoted herein as a second output signal. The negative output signal charges to the second power supply voltage VDD2 in response to the second output node 120 being discharged to ground. The output terminal of the second inverter 110 also couples to the gate of transistor M10. Transistor M10 is also denoted herein as a third transistor. Similarly, transistor M8 is also denoted herein as a fourth transistor.

The negative output signal was already charged high to the first voltage at the rising edge of the positive input signal. Thus, the transistor M10 is initially on before the positive input signal rises high, which allows transistors M8 and P6 to conduct a second current that is mirrored into transistor P5 as a second mirrored current, which causes the second internal node 120 to charge high toward the second power supply voltage VDD2. This charging of the second internal node 120 causes the second inverter 110 to discharge the negative output signal, which switches off transistor M10 to prevent transistor M8 from conducting additional current into ground. In this fashion, power consumption is reduced.

It thus doesn't matter whether the first voltage is less than or greater than the second power supply voltage VDD2. Should the second power supply voltage VDD2 be greater than the first voltage, the pull-down of the first internal node 115 is augmented by transistor M3 in combination with transistor M4. Similarly, the pull-down of the second internal node 120 is augmented by the transistor M6 in combination with transistor M5. Conversely, should the second power supply voltage VDD2 be less than the first voltage, the mirroring of the first current conducted by transistor M7 through the first current mirror formed by transistors P1 and P2 augments the pull-up of the first internal node 115. Similarly, the mirroring of the second current conducted by transistor M8 through the second current mirror formed by transistors P5 and P6 augments the pull-up of the second internal node 120. Transistors M1, M2, M3, M4, M5, and M6 form a pull-down circuit for the level-shifter 100. Similarly, transistors P1 and P2 form a pull-up circuit or for the level-shifter 100 that is augmented by the temporarily-activated first and second current mirrors.

The resulting balancing of the pull-up and pull-down advantageously reduces the duty cycle distortion in the positive and negative output signals across the expected process, voltage, and temperature corners. However, note that there is a parasitic capacitance between the gate and drain of the pull-down transistors M1 and M2. These parasitic capacitances inject charge into the first and second internal nodes 115 and 120 when the input signals transition high. For example, when the positive input signal is discharged, the first internal node 115 is charged to the second power supply voltage VDD2. This voltage difference charges the parasitic capacitance between the gate and the drain of the first pull-down transistor M1. When the positive input signal then transitions from ground to the first voltage, the charged parasitic capacitance of the first pull-down transistor M1 injects charge into the first internal node 115 despite the first pull-down transistor M1 switching on and attempting to discharge the first internal node 115. An analogous injection of charge occurs into the second internal node 120 when the negative input signal transitions from ground to the first voltage. The resulting injection of charge is also denoted as kickback and undesirably disturbs the rising and falling edges of the positive and negative output signals.

To substantially eliminate this charge injection, the coupling capacitor C1 couples between the gate of the first pull-down transistor M1 and the second internal node 120. When the positive input signal is charged to the first voltage, the second internal node 120 is also charged to the second power supply voltage VDD2. Thus, the parasitic capacitive coupling from the gate of the first pull-down transistor M1 to the discharging first internal node 115 is counteracted by the capacitive coupling through the coupling capacitor C1 to the charging second internal node 120. Similarly, the coupling capacitor C2 couples between the gate of the second pull-down transistor M2 and the first internal node 115 to counteract the charge injection from the parasitic capacitance between the gate of the second pull-down transistor M2 and the second internal node 120.

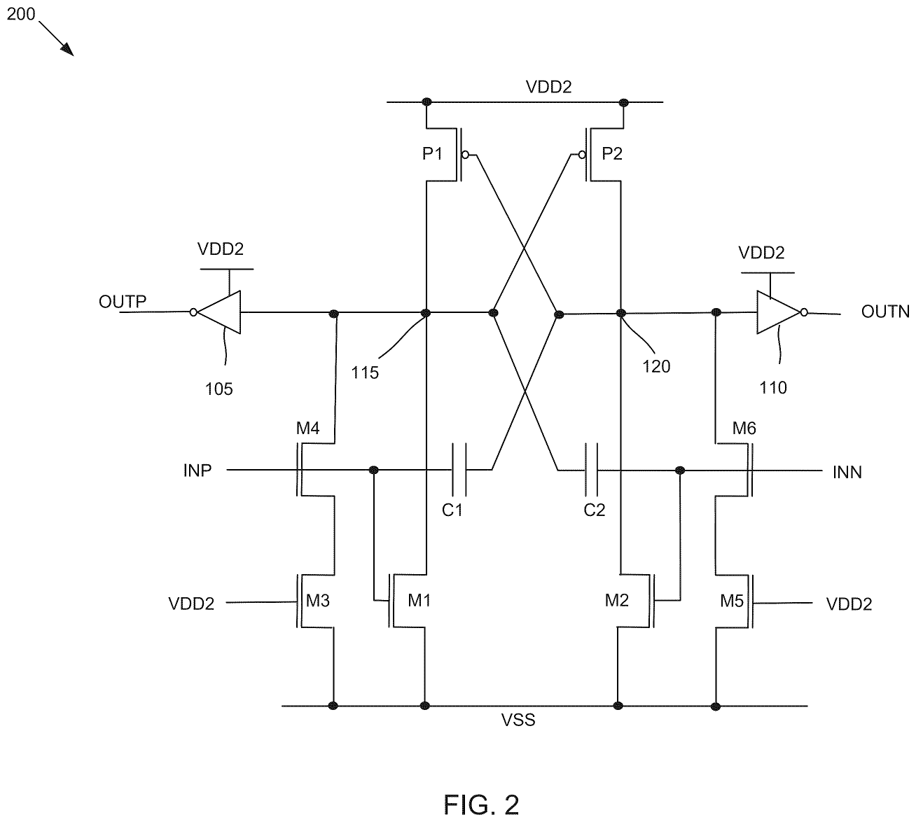

Level-shifter 100 may be modified as shown for a level-shifter 300 of FIG. 2 for applications in which only the second power supply voltage varies. Since the input signal voltages will not vary, the current mirrors may be eliminated. The pull-down circuit or network in level-shifter 200 thus includes the pull-down transistors M1, M2, M3, M4, M5, and M6 arranged as discussed for level-shifter 100. In addition, the coupling capacitors C1 and C2 are arranged as discussed for level-shifter 100. The first inverter 105 inverts the voltage of the first internal node 115 to produce the positive output signal OUTP as also discussed for the level-shifter 100. Similarly, the second inverter 110 inverts the voltage of the second internal node 120 to produce the positive output signal OUTP as also discussed for the level-shifter 100. But level-shifter 200 does not include the current mirrors formed by transistors P3, P4, P5, and P6 nor does it include the transistors M7, M8, M9, and M10.

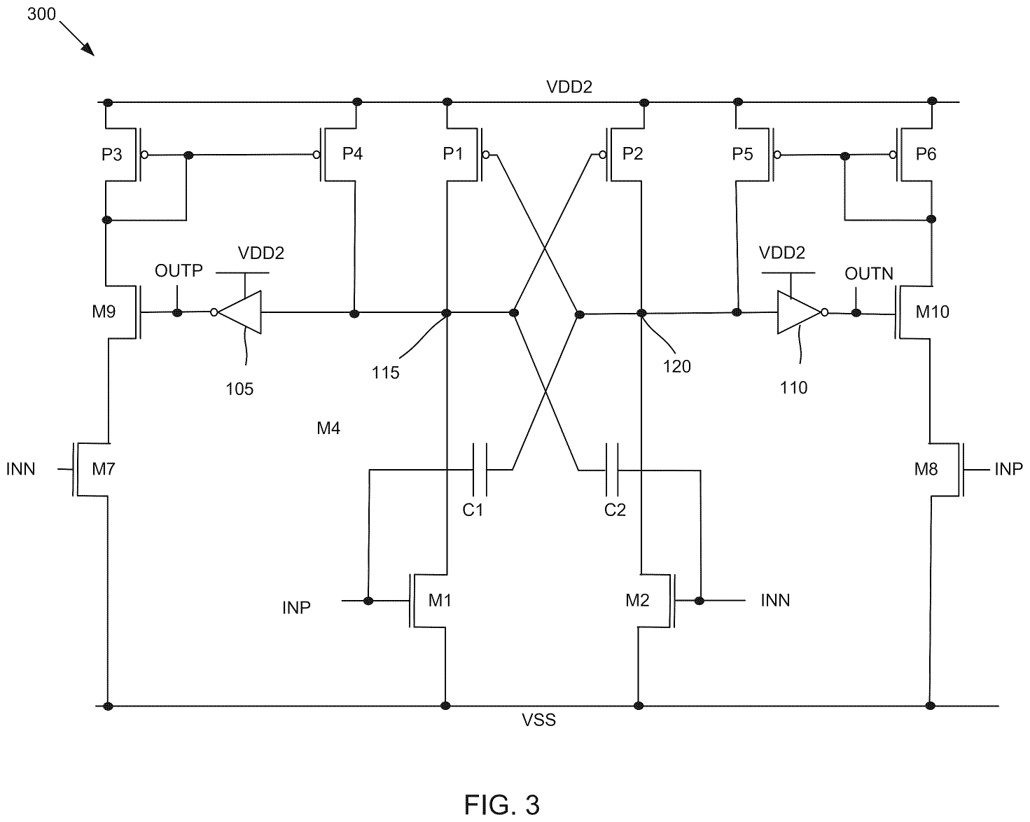

Alternatively, level-shifter 100 may be modified as shown for a level-shifter 300 of FIG. 3 for applications in which only the input signal voltages vary. Since the second power supply voltage VDD2 will not vary, the level-shifter 300 is arranged as discussed for level-shifter 100 except that the pull-down transistors M3, M4, M5, and M6 are eliminated.

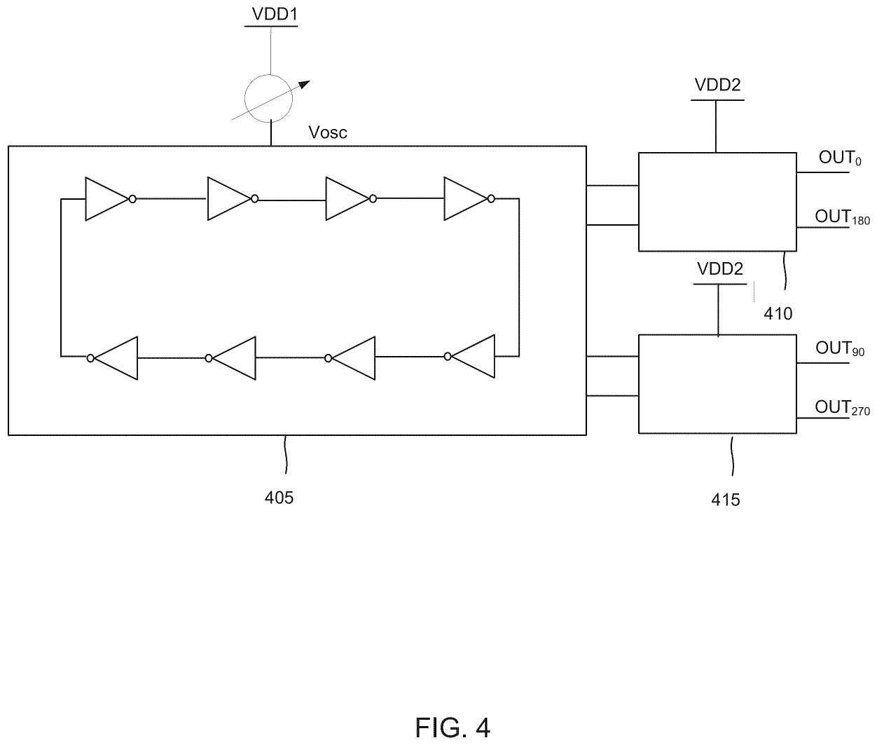

A level-shifter as disclosed herein has numerous applications such as to level-shift output signals from a ring oscillator 405 as shown in FIG. 4. The ring oscillator 405 is powered by a tuned version (Vosc) of a first power supply voltage VDD1. A plurality of inverters within the ring oscillator produces a plurality of oscillating output signals. The oscillation amplitude of the output signals from the ring oscillator 405 depends upon the oscillation frequency, temperature, and process corner. A level-shifter 410 as disclosed herein level-shifts the first pair of output signals from the ring oscillator 405 to produce a 0-degree phase-shifted output signal (OUT₀) and a 180-degree phase-shifted output signal (OUT₁₈₀). Similarly, another level-shifter 415 as disclosed herein level-shifts a second pair of output signals from the ring oscillator 405 to produce a 90-degree phase-shifted output signal (OUT₉₀) and a 270-degree phase-shifted output signal (OUT₂₇₀). The resulting level-shifted ring oscillator may be used to form the voltage-controlled oscillator (VCO) in a phase-locked loop or other suitable application.

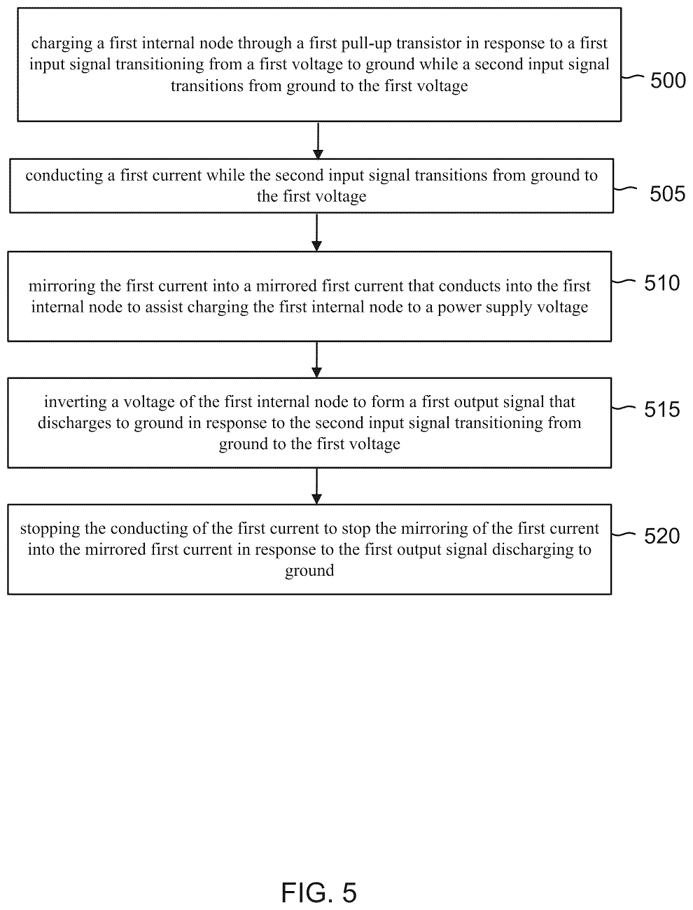

A method of level-shifting will now be discussed with respect to the flowchart of FIG. 5. The method includes an act 500 of charging a first internal node through a first pull-up transistor in response to a first input signal transitioning from a first voltage to ground while a second input signal transitions from ground to the first voltage. The charging of the first internal node 115 in either of the level-shifters 100 or 200 is an example of act 500. The method further includes an act 505 of conducting a first current while the second input signal transitions from ground to the first voltage. The conduction of the first current by the transistor M7 in either of the level-shifters 100 or 200 is an example of act 505. In addition, the method includes an act 510 of mirroring the first current into a mirrored first current that conducts into the first internal node to assist charging the first internal node to a power supply voltage. The mirroring of the first current through the first current mirror formed by the diode-connected transistor P3 and the transistor P4 in either of the level-shifters 100 or 200 is an example of act 510. The method also includes an act 515 of inverting a voltage of the first internal node to form a first output signal that discharges to ground in response to the second input signal transitioning from ground to the first voltage.

The inversion in first inverter 105 in either of the level-shifters 100 or 200 is an example of act 515. Finally, the method includes an act 520 of stopping the conducting of the first current to stop the mirroring of the first current into the mirrored first current in response to the first output signal discharging to ground. The switching off of the transistor M9 in either of the level-shifters 100 or 200 is an example of act 520.

The disclosure will now be summarized in the following example clauses:

Clause 1. A level-shifter, comprising:
a pull-down circuit configured to ground a first internal node in response to a first input signal being charged to a first voltage;
a pull-up circuit configured to charge the first internal node to a power supply voltage in response to the first input signal being discharged from the first voltage to ground;
a first inverter configured to invert a voltage of the first internal node to form a first output signal at an output terminal of the first inverter;
a first transistor having a gate coupled to the output terminal of the first inverter;
a second transistor coupled between the first transistor and ground and having a gate coupled to a node for the first input signal; and
a first current mirror configured to mirror a current conducted by the first transistor into a mirrored current conducted into the first internal node.
   Clause 2. The level-shifter of clause 1, wherein the pull-down circuit is further configured to ground a second internal node in response to a second input signal being charged to the first voltage, wherein the second input signal is a complement of the first input signal, and wherein the pull-up circuit is further configured to charge the second internal node to the power supply voltage in response to the second input signal being discharged from the first voltage to ground, the level-shifter further comprising:
a second inverter configured to invert a voltage of the second internal node to form a second output signal at an output terminal of the second inverter, wherein the second output signal is a complement of the first output signal;
a third transistor having a gate coupled to the output terminal of the second inverter;
a fourth transistor coupled between the third transistor and ground and having a gate coupled to a node for the second input signal; and
a second current mirror configured to mirror a current conducted by the third transistor into a mirrored current conducted into the second internal node.
   Clause 3. The level-shifter of clause 2, wherein the first transistor is an n-type metal-oxide semiconductor (NMOS) transistor, and wherein the second transistor is a NMOS transistor having a source coupled to ground and a drain coupled to a source of the first transistor.
   Clause 4. The level-shifter of clause 3, wherein the first current mirror comprises a diode-connected first p-type metal-oxide semiconductor (PMOS) transistor having a source coupled to the node for the power supply voltage, a drain coupled to a drain of the first transistor, and a gate coupled to a gate of a second PMOS transistor having a source coupled to the node for the power supply voltage and a drain coupled to the first internal node.
   Clause 5. The level-shifter of clause 4, wherein the second current mirror comprises a diode-connected third p-type metal-oxide semiconductor (PMOS) transistor having a source coupled to the node for the power supply voltage, a drain coupled to a drain of the third transistor, and a gate coupled to a gate of a fourth PMOS transistor having a source coupled to the node for the power supply voltage and a drain coupled to the second internal node.
   Clause 6. The level-shifter of any of clauses 2-5, wherein the pull-down circuit comprises:
a first pull-down transistor coupled between the first internal node and ground and having a gate coupled to the node for the first input signal;
a second pull-down transistor coupled between the second internal node and ground and having a gate coupled to the node for the second input signal, and wherein the pull-up circuit comprises:
a first pull-up transistor coupled between the first internal node and the node for the power supply voltage and having a gate coupled to the second internal node; and
a second pull-up transistor coupled between the second internal node and the node for the power supply voltage and having a gate coupled to the first internal node.
   Clause 7. The level-shifter of clause 6, wherein the pull-down circuit further includes:
a third pull-down transistor and a fourth pull-down transistor coupled in series between the first internal node and ground, wherein a gate of the third pull-down transistor is coupled to the node for the power supply voltage, and wherein a gate of the fourth pull-down transistor is coupled to the node for the first input signal.
   Clause 8. The level-shifter of clause 7, wherein the pull-down circuit further includes:
a fifth pull-down transistor and a sixth pull-down transistor coupled in series between the second internal node and ground, wherein a gate of the fifth pull-down transistor is coupled to the node for the power supply voltage, and wherein a gate of the sixth pull-down transistor is coupled to the node for the second input signal.
   Clause 9. The level-shifter of any of clauses 6-8, further comprising:
a first capacitor coupled between the gate of the first pull-down transistor and the second internal node; and
a second capacitor coupled between the gate of the second pull-down transistor and the first internal node.
   Clause 10. A method of level-shifting, comprising:
charging a first internal node through a first pull-up transistor in response to a first input signal transitioning from a first voltage to ground while a second input signal transitions from ground to the first voltage;
conducting a first current while the second input signal transitions from ground to the first voltage;
mirroring the first current into a mirrored first current that conducts into the first internal node to assist charging the first internal node to a power supply voltage;
inverting a voltage of the first internal node to form a first output signal that discharges to ground in response to the second input signal transitioning from ground to the first voltage; and
stopping the conducting of the first current to stop the mirroring of the first current into the mirrored first current in response to the first output signal discharging to ground.
   Clause 11. The method of clause 10, further comprising:
charging a second internal node through a second pull-up transistor in response to the second input signal transitioning from the first voltage to ground while the first input signal transitions from ground to the first voltage;
conducting a second current while the first input signal transitions from ground to the first voltage;
mirroring the second current into a mirrored second current that conducts into the second internal node to assist charging of the second internal node to the power supply voltage;
inverting a voltage of the second internal node to form a second output signal that discharges to ground in response to the second input signal transitioning from ground to the first voltage; and
stopping the conducting of the second current to stop the mirroring of the second current into the mirrored second current in response to the second output signal discharging to ground.
   Clause 12. The method of any of clauses 11-12, further comprising:
producing the first input signal and the second input signal in a ring oscillator.
   Clause 13. The method of any of clauses 10-12, wherein conducting the first current comprises switching on an n-type metal-oxide semiconductor (NMOS) transistor to conduct the first current.
   Clause 14. The method of any of clauses 10-13, wherein mirroring the first current through the current mirror comprises;
conducting the first current through a first diode-connected transistor having a source coupled to a node for the power supply voltage; and
coupling a gate of the first diode-connected transistor to a second transistor having a source coupled to the node for the power supply voltage to cause the second transistor to conduct the mirrored second current into the first internal node.
   Clause 15. A level-shifter, comprising:
a first internal node;
a first pull-down transistor coupled between the first internal node and ground and having a gate coupled to a node for a first input signal;
a second internal node;
a second pull-down transistor coupled between the second internal node and ground and having a gate coupled to a node for a second input signal;
a first pull-up transistor coupled between the first internal node and a node for a power supply voltage and having a gate coupled to the second internal node;
a second pull-up transistor coupled between the second internal node and the node for the power supply voltage and having a gate coupled to the first internal node;
a first capacitor coupled between the gate of the first pull-down transistor and the second internal node; and
a second capacitor coupled between the gate of the second pull-down transistor and the first internal node.
   Clause 16. The level-shifter of clause 15, further comprising:
a first inverter configured to invert a voltage of the first internal node to produce a first output signal; and
a second inverter configured to invert a voltage of the second internal node to produce a second output signal that is a complement of the first output signal.
   Clause 17. The level-shifter of clause 16, wherein the first inverter includes a power terminal coupled to the node for the power supply voltage, and wherein the second inverter includes a power terminal coupled to the node for the power supply voltage.
   Clause 18. The level-shifter of clause 16, further comprising:
a third pull-down transistor and a fourth pull-down transistor coupled in series between the first internal node and ground, wherein a gate of the third pull-down transistor is coupled to the node for the power supply voltage, and wherein a gate of the fourth pull-down transistor is coupled to the node for the first input signal.
   Clause 19. The level-shifter of clause 18, further comprising:
a fifth pull-down transistor and a sixth pull-down transistor coupled in series between the second internal node and ground, wherein a gate of the fifth pull-down transistor is coupled to the node for the power supply voltage, and wherein a gate of the sixth pull-down transistor is coupled to the node for the second input signal.
   Clause 20. The level-shifter of any of clauses 15-19, wherein the first pull-down transistor and the second pull-down transistor each comprises an NMOS transistor, and wherein the first pull-up transistor and the second pull-up transistor each comprises a PMOS transistor.

As those of some skill in this art will by now appreciate and depending on the particular application at hand, many modifications, substitutions and variations can be made in and to the materials, apparatus, configurations and methods of use of the devices of the present disclosure without departing from the scope thereof. In light of this, the scope of the present disclosure should not be limited to that of the particular implementations illustrated and described herein, as they are merely by way of some examples thereof, but rather, should be fully commensurate with that of the claims appended hereafter and their functional equivalents.

We claim:

1. A level-shifter, comprising:
a pull-down circuit configured to ground a first internal node in response to a first input signal being charged to a first voltage;
a pull-up circuit configured to charge the first internal node to a power supply voltage in response to the first input signal being discharged from the first voltage to ground;
a first inverter configured to invert a voltage of the first internal node to form a first output signal at an output terminal of the first inverter;
a first transistor having a gate coupled to the output terminal of the first inverter;
a second transistor coupled between the first transistor and ground and having a gate coupled to a node for the first input signal; and
a first current mirror configured to mirror a current conducted by the first transistor into a mirrored current conducted into the first internal node.

2. The level-shifter of claim 1, wherein the pull-down circuit is further configured to ground a second internal node in response to a second input signal being charged to the first voltage, wherein the second input signal is a complement of the first input signal, and wherein the pull-up circuit is further configured to charge the second internal node to the power supply voltage in response to the second input signal being discharged from the first voltage to ground, the level-shifter further comprising:
a second inverter configured to invert a voltage of the second internal node to form a second output signal at an output terminal of the second inverter, wherein the second output signal is a complement of the first output signal;
a third transistor having a gate coupled to the output terminal of the second inverter;
a fourth transistor coupled between the third transistor and ground and having a gate coupled to a node for the second input signal; and
a second current mirror configured to mirror a current conducted by the third transistor into a mirrored current conducted into the second internal node.

3. The level-shifter of claim 2, wherein the first transistor is an n-type metal-oxide semiconductor (NMOS) transistor, and wherein the second transistor is a NMOS transistor having a source coupled to ground and a drain coupled to a source of the first transistor.

4. The level-shifter of claim 3, wherein the first current mirror comprises a diode-connected first p-type metal-oxide semiconductor (PMOS) transistor having a source coupled to the node for the power supply voltage, a drain coupled to a drain of the first transistor, and a gate coupled to a gate of a second PMOS transistor having a source coupled to the node for the power supply voltage and a drain coupled to the first internal node.

5. The level-shifter of claim 4, wherein the second current mirror comprises a diode-connected third p-type metal-oxide semiconductor (PMOS) transistor having a source coupled to the node for the power supply voltage, a drain coupled to a drain of the third transistor, and a gate coupled to a gate of a fourth PMOS transistor having a source coupled to the node for the power supply voltage and a drain coupled to the second internal node.

6. The level-shifter of claim 2, wherein the pull-down circuit comprises:
a first pull-down transistor coupled between the first internal node and ground and having a gate coupled to the node for the first input signal;
a second pull-down transistor coupled between the second internal node and ground and having a gate coupled to the node for the second input signal, and wherein the pull-up circuit comprises:
a first pull-up transistor coupled between the first internal node and the node for the power supply voltage and having a gate coupled to the second internal node; and
a second pull-up transistor coupled between the second internal node and the node for the power supply voltage and having a gate coupled to the first internal node.

7. The level-shifter of claim 6, wherein the pull-down circuit further includes:
a third pull-down transistor and a fourth pull-down transistor coupled in series between the first internal node and ground, wherein a gate of the third pull-down transistor is coupled to the node for the power supply voltage, and wherein a gate of the fourth pull-down transistor is coupled to the node for the first input signal.

8. The level-shifter of claim 7, wherein the pull-down circuit further includes:
a fifth pull-down transistor and a sixth pull-down transistor coupled in series between the second internal node and ground, wherein a gate of the fifth pull-down transistor is coupled to the node for the power supply voltage, and wherein a gate of the sixth pull-down transistor is coupled to the node for the second input signal.

9. The level-shifter of claim 6, further comprising:
a first capacitor coupled between the gate of the first pull-down transistor and the second internal node; and
a second capacitor coupled between the gate of the second pull-down transistor and the first internal node.

10. A method of level-shifting, comprising:
charging a first internal node through a first pull-up transistor in response to a first input signal transitioning from a first voltage to ground while a second input signal transitions from ground to the first voltage;
conducting a first current while the second input signal transitions from ground to the first voltage;
mirroring the first current into a mirrored first current that conducts into the first internal node to assist charging the first internal node to a power supply voltage;
inverting a voltage of the first internal node to form a first output signal that discharges to ground in response to the second input signal transitioning from ground to the first voltage; and
stopping the conducting of the first current to stop the mirroring of the first current into the mirrored first current in response to the first output signal discharging to ground.

11. The method of claim 10, further comprising:
charging a second internal node through a second pull-up transistor in response to the second input signal transitioning from the first voltage to ground while the first input signal transitions from ground to the first voltage;
conducting a second current while the first input signal transitions from ground to the first voltage;
mirroring the second current into a mirrored second current that conducts into the second internal node to assist charging of the second internal node to the power supply voltage;
inverting a voltage of the second internal node to form a second output signal that discharges to ground in response to the second input signal transitioning from ground to the first voltage; and
stopping the conducting of the second current to stop the mirroring of the second current into the mirrored second current in response to the second output signal discharging to ground.

12. The method of claim 11, further comprising:
producing the first input signal and the second input signal in a ring oscillator.

13. The method of claim 10, wherein conducting the first current comprises switching on an n-type metal-oxide semiconductor (NMOS) transistor to conduct the first current.

14. The method of claim 10, wherein mirroring the first current through the current mirror comprises;
conducting the first current through a first diode-connected transistor having a source coupled to a node for the power supply voltage; and
coupling a gate of the first diode-connected transistor to a second transistor having a source coupled to the node for the power supply voltage to cause the second transistor to conduct the mirrored second current into the first internal node.

15. A level-shifter, comprising:
a first internal node;
a first pull-down transistor coupled between the first internal node and ground and having a gate coupled to a node for a first input signal;
a second internal node;
a second pull-down transistor coupled between the second internal node and ground and having a gate coupled to a node for a second input signal;
a first pull-up transistor coupled between the first internal node and a node for a power supply voltage and having a gate coupled to the second internal node;
a second pull-up transistor coupled between the second internal node and the node for the power supply voltage and having a gate coupled to the first internal node;
a first capacitor coupled between the gate of the first pull-down transistor and the second internal node; and
a second capacitor coupled between the gate of the second pull-down transistor and the first internal node.

16. The level-shifter of claim 15, further comprising:
a first inverter configured to invert a voltage of the first internal node to produce a first output signal; and
a second inverter configured to invert a voltage of the second internal node to produce a second output signal that is a complement of the first output signal.

17. The level-shifter of claim 16, wherein the first inverter includes a power terminal coupled to the node for the power supply voltage, and wherein the second inverter includes a power terminal coupled to the node for the power supply voltage.

18. The level-shifter of claim 16, further comprising:
a third pull-down transistor and a fourth pull-down transistor coupled in series between the first internal node and ground, wherein a gate of the third pull-down transistor is coupled to the node for the power supply voltage, and wherein a gate of the fourth pull-down transistor is coupled to the node for the first input signal.

19. The level-shifter of claim 18, further comprising:
a fifth pull-down transistor and a sixth pull-down transistor coupled in series between the second internal node and ground, wherein a gate of the fifth pull-down transistor is coupled to the node for the power supply voltage, and wherein a gate of the sixth pull-down transistor is coupled to the node for the second input signal.

20. The level-shifter of claim 15, wherein the first pull-down transistor and the second pull-down transistor each comprises an NMOS transistor, and wherein the first pull-up transistor and the second pull-up transistor each comprises a PMOS transistor.
